(19) United States
(12) Patent Application Publication
(10) Pub. No.: US 2003/0141571 A1
(43) Pub. Date: Jul. 31, 2003

(54) Semiconductor device and manufacturing method thereof

(76) Inventor: Masaaki Itoh, Tokyo (JP)

Correspondence Address: JONES, VOLENTINE, STEINBERG & WHITT, L.L.P., Suite 150, 12200 Sunrise Valley Drive, Reston, VA, 20191, US

(21) Appl. No.: 10/366,344

(22) Filed: Feb. 14, 2003

Related U.S. Application Data
(62) Division of application No. 09/635,574, filed on Aug. 9, 2000.

(30) Foreign Application Priority Data
Sep. 3, 1999 (JP) 250046/99

(51) Int. Cl. H01L 29/40

(52) U.S. Cl. 257/621

(57) ABSTRACT

A recess is formed in a semiconductor substrate and a contact hole is formed in a bottom region of the recess. Circuit elements on a main surface of the semiconductor substrate are connected to conductive elements on an opposite surface of the substrate through the contact hole in the recess.

### FIELD OF THE INVENTION

The present invention relates to a semiconductor device and to method of manufacture, and more particularly, the present invention relates to a semiconductor memory device having a contact hole which connects a main surface of a substrate with an opposite surface of the substrate, and to a method of manufacturing such a semiconductor device.

### BACKGROUND OF THE INVENTION

In a high frequency monolithic IC (MMIC), both surfaces of a semiconductor substrate are used in order to reduce the size of the IC or realize a high integration.

In such an IC, contact holes which penetrate through the semiconductor substrate connect conductive lines on a main surface with conductive line on an opposite surface. Generally, circuit elements are formed on the main surface and a ground line is formed on the opposite surface.

In the MMIC which is required to work at a high speed, a semiconductor substrate which comprises gallium arsenide (hereinafter, a GaAs substrate) is used. In such a compound semiconductor device, field effect transistors (FETs) are formed on the main surface and a metallic conductive line which is electrically connected to a ground is formed on the opposite surface.

In a method for fabricating such a device, the FETs are first formed on the main surface of the GaAs substrate. Then, the opposite surface is polished so as to reduce a thickness of the GaAs substrate. Next, contact holes penetrating through the GaAs substrate are formed in the substrate. Then, the contact holes are filled with conductive material and predetermined conductive lines are formed on both surfaces which are electrically connected to the conductive material in the contact holes.

In such a method, the contact holes are formed after polishing the substrate. Generally, such polishing makes the thickness of the substrate less than 100 μm. This reduced thickness restrains an expanded diameter of the contact hole on the opposite surface, reduces resistance between the metallic line for the ground and electrodes of the FETs which are respectively connected to the predetermined conductive lines, improves output characteristics of the FETs. However, as the substrate is made thinner, the strength of the substrate is reduced. In particular, since the GaAs substrate is inherently fragile, a reduction in strength can have significant consequences.

If the strength of the substrate is reduced, the substrate may be easily warped by various stresses encountered during semiconductor processes. At worst, the substrate might be broken. Also, if a diameter of the semiconductor wafer is large, such warping can be especially problematic.

To avoid such a problem, a support substrate, such as an alumina substrate, may be attached to the substrate. However, this technique suffers drawbacks in that it is relatively complicated.

### SUMMARY OF THE INVENTION

An object of the invention is to provide a semiconductor device having a contacting hole which connects a main surface of a substrate with an opposite surface of the substrate while maintaining a strength of the substrate so as to reduce the size of the semiconductor device and realize a high integration.

To achieve this object, in the one embodiment of the present invention, a recess is formed in the substrate and a contact hole is formed in the bottom of the recess. Circuit elements on the main surface are connected to conductive elements on the opposite surface through the contact hole in the recess.

According to the present invention, circuits elements on the main surface can be connected with the conductive element on the opposite surface while maintaining the strength of the substrate.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1(A)-FIG. 1(D) are cross-sectional views describing a method of fabricating a semiconductor device according to a first preferred embodiment.

FIG. 2(A)-FIG. 2(C) are cross-sectional views describing a method of fabricating a semiconductor device according to a second preferred embodiment.

FIG. 3(A)-FIG. 3(C) are cross-sectional views describing a method of fabricating a semiconductor device according to a third preferred embodiment.

FIG. 4(A)-FIG. 4(B) are cross-sectional views describing a method of fabricating a semiconductor device according to a fourth preferred embodiment.

FIG. 5(A)-FIG. 5(B) are cross-sectional views describing a method of fabricating a semiconductor device according to a fifth preferred embodiment.

### DESCRIPTION OF THE PREFERRED EMBODIMENTS

The present invention will be described hereinafter with reference to the accompanying drawings. The drawings used for this description typically illustrate major characteristic parts in order that the present invention will be easily understood.

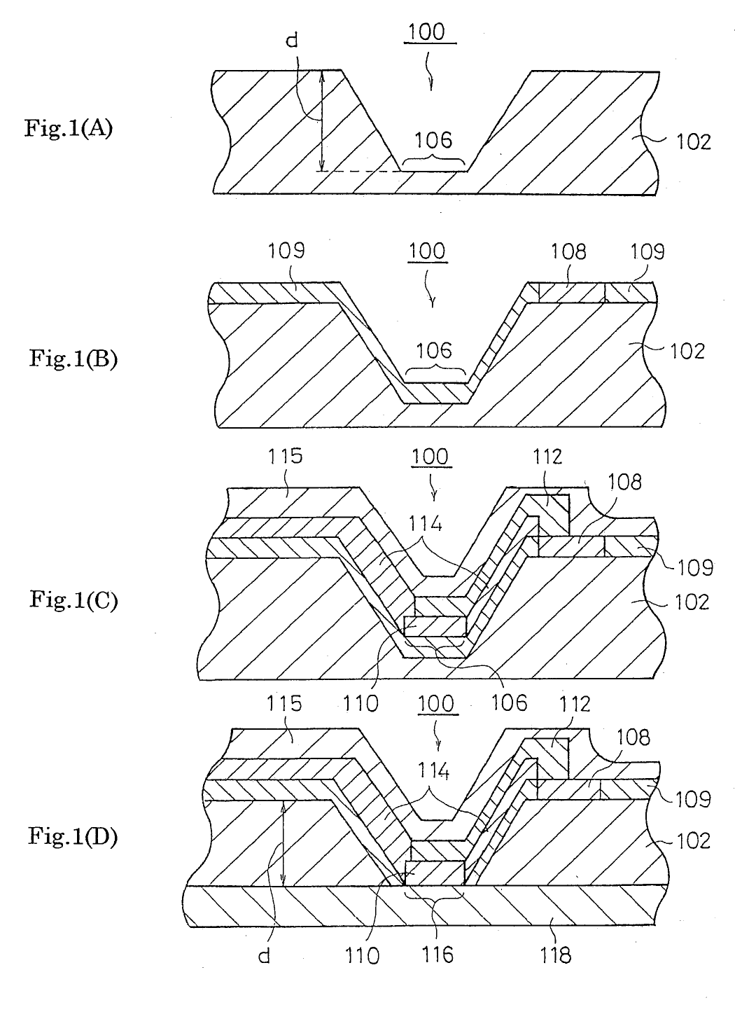

A first preferred embodiment will be described hereinafter referring to FIG. 1(A)-FIG. 1(D). In this embodiment, a GaAs substrate 102 which is comprised of gallium arsenide (hereinafter, a GaAs substrate) is used as a semiconductor substrate. However, the invention is not limited to the GaAs substrate. Other substrates, such as other compound semiconductor substrates, a silicon substrate, and a glass substrate can be used as the substrate in this embodiment.

A recess 100 is formed in a main surface of the GaAs substrate 102 by a wet etching method or a dry etching method, as shown in FIG. 1(A). The GaAs substrate 102 has the main surface and an opposite surface which is opposite the main surface. The recess 100 is a depression which is formed in the substrate 102. A contact hole will be later defined in the bottom region 106 of the recess 100 hereinafter. In the etching process for the recess 100, a depth of the recess 100 is defined so as to substantially equal to a final depth of the substrate (a depth d in FIG. 1(D)).

An impurity layer 109 which includes an impurity is formed on the substrate 102 including an interior surface of the recess 100, as shown in FIG. 1(B). The impurity later is formed by an ion implantation method, a molecular beam epitaxial growth method (MBE method) or a metal organic chemical vapor deposition method (MOCVD method). Also, the impurity layer 109 can be formed by a vapor phase epitaxial growth method, a liquid phase epitaxial growth method, a plasma chemical vapor deposit method, a laser chemical vapor deposit method, a sputtering method or a vacuum evaporation method.

Then, a FET region (a channel region of a FET) 108 is selectively formed in the impurity layer 109 by the ion implantation method. That is, the FET region 108 is formed on the main surface which is outside of the recess 100. Also, the FET region 108 can be formed by a solid phase diffusion method, a vapor phase diffusion method, a laser doping method or a plasma doping method. In this embodiment, the FET region 108 is a source electrode of the FET.

Then, in FIG. 1(C), a source pad 110 is formed in the bottom region 106. An intermediate insulating layer 114 is formed on the impurity layer 109 so as to expose the source pad 110 and the FET region 108. A conductive line 112 which connects the source pad 110 with the FET region 108 is formed on the intermediate insulating layer 114. A passivating film 115 is formed on the FET region 108, the source pad 110 and the conductive line 112. In this embodiment, the source pad is described as an example. Also, a gate pad which is connected to a gate electrode of the FET, or a drain pad which is connected to a drain electrode of the FET may be used.

The source pad 110 and the conductive line 112 are comprised of a metallic material, such as copper (Cu) or aluminum (Al), and is formed by an electron beam deposition method, a sputtering method, a vacuum evaporation method, a chemical vapor deposit method or a palting, and they are then patterned.

Then, a contact hole 116 is defined in the bottom region 106 of the recess 100 by polishing the opposite surface of the substrate 102, as shown in FIG. 1(D). In this polishing process, the opposite surface of the substrate 102 is polished so as to expose a portion of the source pad 106 from the side of the opposite surface. That is, the substrate 102 is polished so as to be a predetermined depth d.

In a conventional etching process for forming such a contact hole, a diameter of the contact hole on the opposite surface is expanded by a side etching effect. On the contrary, as the polishing process is used in this embodiment, such expansion of the contacting hole can be substantially restrained.

Then, a metallic layer 118 is formed on the opposite surface of the substrate 102. In this embodiment, gold (Au) is used as the metallic layer 118. As the portion of the source pad 110 is exposed from the side of the opposite surface, the metallic layer 118 is connected to the source pad 110 at the bottom region of the recess 100.

According to the first preferred embodiment, as polishing of the substrate and forming the contact hole can be carried out simultaneously, processing steps can be shortened. Further, as formation of the contact hole is not necessary after polishing the substrate to make it thinner, the substrate does not warp. The invention is particularly effective for the GaAs substrate due to its fragility.

Also, as a length of the contact hole becomes shorter according to the first embodiment, a resistance in the contact hole can be lowered. Further, An aspect ratio is lower than that of the conventional contact hole. If an etching method is used for forming the contact hole, an expansion of the diameter of the contact hole by a side etching effect can be restrained.

Further, as it is not necessary to polish the substrate even thinner to reduce the aspect ratio of the contact hole, as compared with the conventional polishing, the strength of the substrate can be maintained. Therefore, warping of the substrate is restrained. By adjusting a depth of the recess or a location of the contact hole, the length of the contact hole can be selectively defined.

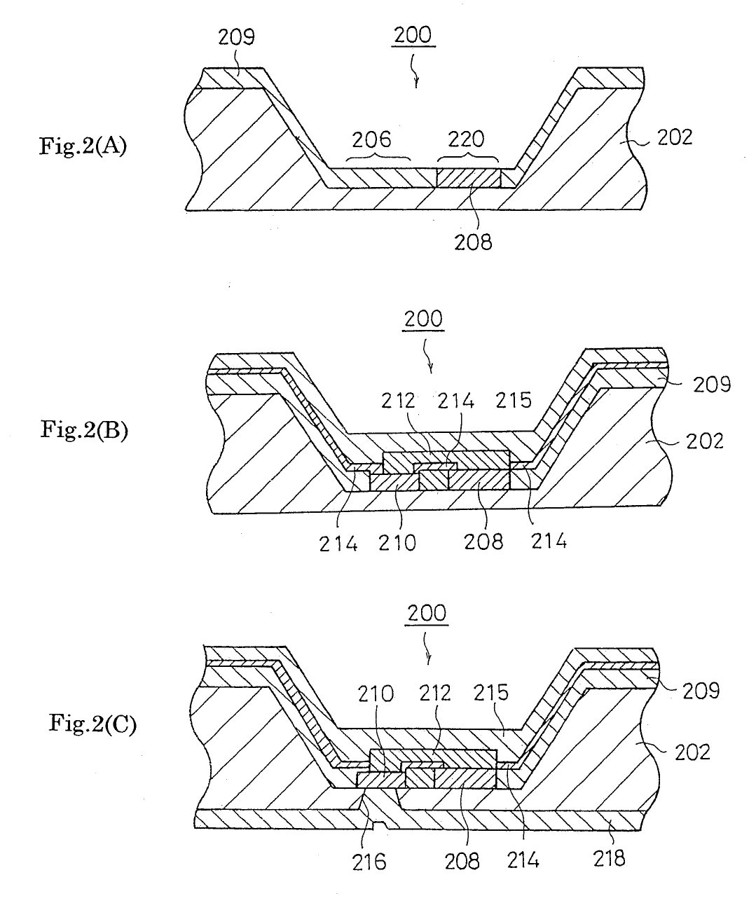

A second preferred embodiment will be described hereinafter referring to FIG. 2(A)-FIG. 2(C).

A recess 200 is formed in a main surface of a GaAs substrate 202 by a wet etching method or a dry etching method, as shown in FIG. 2(A). The recess 200 includes a first region 206 in which a contact hole will be later defined and a second region 220 in which a FET region will be later formed hereinafter. A diameter of the recess 200 is wider than that of the recess 100 of the first preferred embodiment.

Similar to the first embodiment, an impurity layer 209 which includes an impurity is formed on the substrate 202 including an interior surface of the recess 200, as shown in FIG. 2(A). Then, a FET region 208 is selectively formed in the impurity layer 209 by an ion implantation method. That is, the FET region 208 is formed on the second region 220 in the recess 200.

Then, the impurity region 209 on the first region 206 is removed so as to expose a portion of the bottom of the recess and a source pad 210 is formed on the exposed bottom of the recess 200, as shown in FIG. 2(B). An intermediate insulating layer 214 is formed on the impurity layer 209 so as to expose the source pad 210 and the FET region 208. A conductive line 212 which connects the source pad 210 with the FET region 208 is formed on the intermediate insulating layer 214. A passivating film 215 is formed on the FET region 208, the source pad 210 and the conductive line 212.

A contact hole 216 which penetrates through the substrate from the opposite surface to the first region 206 is formed by an etching method. Thereby, a portion of the source pad 210 is exposed through the contact hole 216, as shown in FIG. 2(C).

Then, a metallic layer 218 is formed on the opposite surface of the substrate 202. As the portion of the source pad 210 is exposed from the side of the opposite surface, the metallic layer 218 is connected to the source pad 210 at the first region 206. Gold (Au) is used as the metallic layer 218.

According to the second embodiment, as the FET is formed in the recess, the substrate can be made thinner than that of the first preferred embodiment. Thereby, heat which occurs from the FET on the main surface can be radiated from the main surface to the opposite surface. Thereby, heat induced variation of the FET can be reduced. As a diameter of the recess in this embodiment is wider than that of the first embodiment, formation of the recess can be easily carried out.

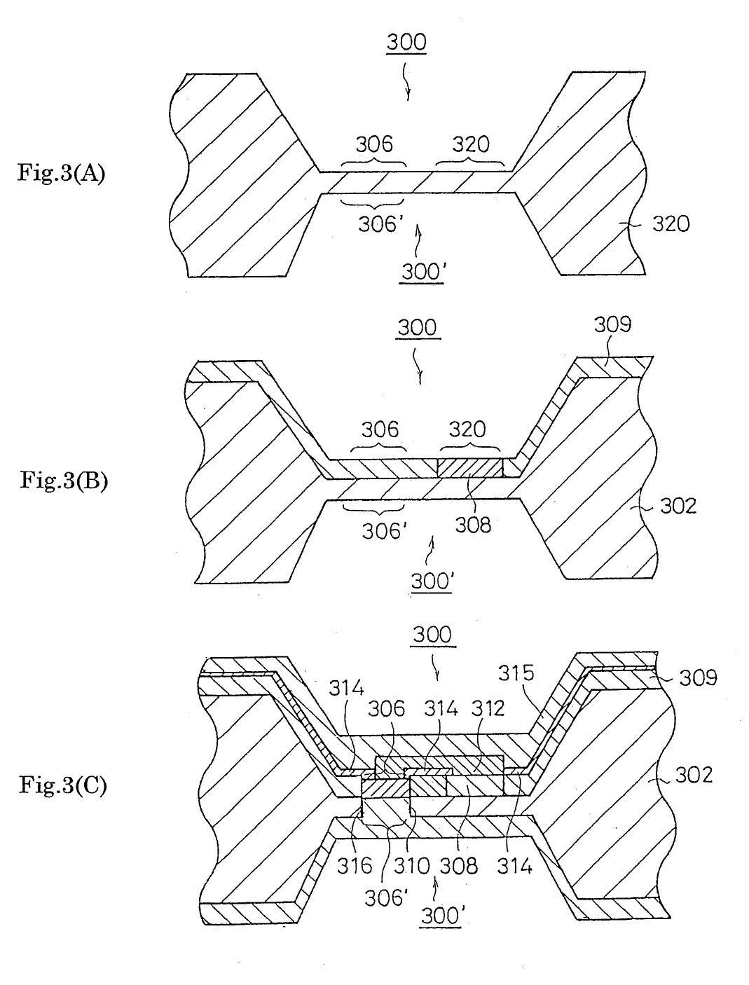

A third preferred embodiment will be described hereinafter referring to FIG. 3(A)-FIG. 3(C).

Recesses 300, 300′ are formed in a main surface and a opposite surface of a GaAs substrate 320 by a wet etching method or a dry etching method, as shown in FIG. 3(A). The recess 300′ is formed on the opposite surface directly under the recess 300. The recess 300 includes a first region 306 in which a contact hole will be later formed and a second region 320 in which a FET region will be later formed. Also, the recess 300′ includes a third region 306′ in which the contact hole will be later formed. Similar to the second embodiment, a diameter of the recesses 300, 300′ is wider than that of the recess 100 of the first preferred embodiment.

Similar to the second embodiment, an impurity layer 309 which includes an impurity is formed on the substrate 302 including an interior surface of the recess 300, as shown in FIG. 3(B). Then, a FET region 308 is selectively formed in the impurity layer 309 by an ion implantation method. That is, the FET region 308 is formed on the second region 320 in the recess 300.

Then, the impurity region 309 on the first region 306 is removed so as to expose a portion of the bottom of the recess and a source pad 310 is formed on the exposed bottom of the recess 300. An intermediate insulating layer 314 is formed on the impurity layer 309 so as to expose the source pad 310 and the FET region 308. A conductive line 312 which connects the source pad 310 with the FET region 308 is formed on the intermediate insulating layer 314. A passivating film 315 is formed on the FET region 308, the source pad 310 and the conductive line 212.

A contact hole 316 which penetrates through the substrate from the third region 306′ to the first region 306 is formed by an etching method. Thereby, a portion of the source pad 310 is exposed through the contact hole 316.

Then, a metallic layer 318 is formed on the opposite surface of the substrate 302. As the portion of the source pad 310 is exposed from the side of the opposite surface, the metallic layer 318 is connected to the source pad 310 at the first region 306.

According to the third embodiment, a length of the contact hole and a thickness of the substrate in a vicinity of the FETs can be adjusted by a depth of either the recess 300 or the recess 300′. That is, if the configuration of the recess on the main surface is limited by a circuit design, the length of the hole and the thickness of the substrate can be controlled by the configuration of the recess on the opposite surface.

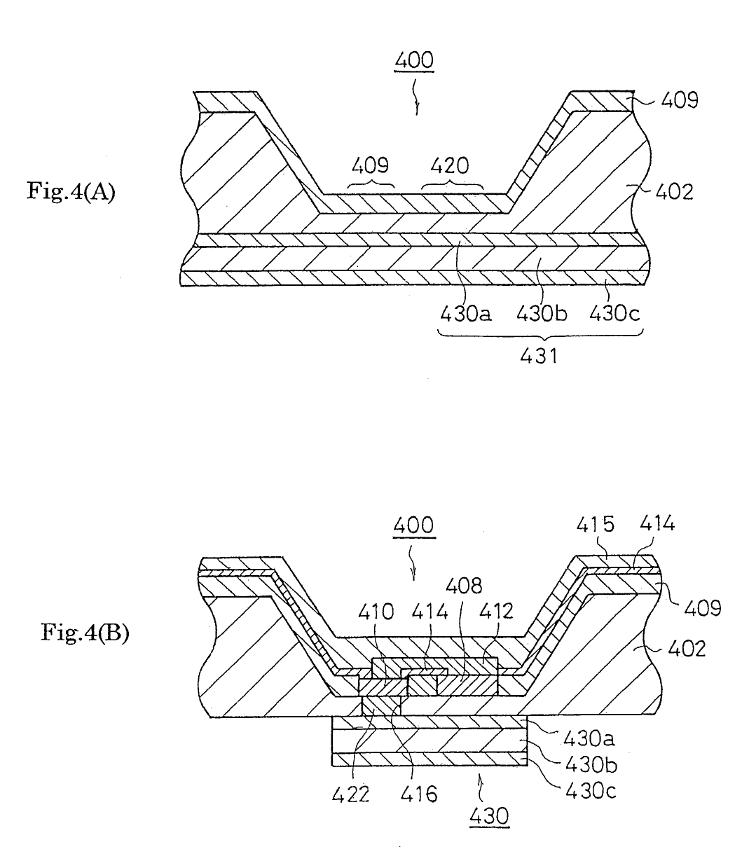

A fourth preferred embodiment will be described hereinafter referring to FIG. 4(A)-FIG. 4(B). In this embodiment, an inductor is formed on the opposite surface instead of the metallic layer shown in FIG. 2(C) of the second preferred embodiment.

A recess 400 is formed in a main surface of a GaAs substrate 402 by a wet etching method or a dry etching method, as shown in FIG. 4(A). The recess 400 includes a first region 409 in which a contact hole will be later formed hereinafter and a second region 420 in which a FET region will be later formed hereinafter. An impurity layer 409 which includes an impurity is formed on the substrate 402 including an interior surface of the recess 400, as shown in FIG. 4(A).

Then, an opposite surface is polished away such that a thickness of the substrate 402 becomes a predetermined thickness.

A thin film 403a which is comprised of a refractory metal, such as tungsten (W), tungsten silicide (WSi) or molybdenum (Mo), is formed on the opposite surface. The thin film 403a is formed by a sputtering method or a CVD method. Then, a gold (Au) layer 430b is plated on the thin film 403a. Further, a thin layer 403c which is comprised of the refractory metal, such as tungsten (W), is formed on the gold layer 430b.

In FIG. 4(B), a FET region 408 is selectively formed in the impurity layer 409 by an ion implantation method. That is, the FET region 408 is formed on the second region 420 in the recess 400.

Then, a contact hole 416 which reaches the thin film 430a is formed in the first region by etching from the side of the main surface. A contact metallic layer 422 is filled in the contacting hole 416 and a source pad 410 is formed on the contact layer 422, as shown in FIG. 4(B).

Then, an intermediate insulating layer 414 is formed on the impurity layer 409 so as to expose the source pad 410 and the FET region 408. A conductive line 412 which connects the source pad 410 with the FET region 408 is formed on the intermediate insulating layer 414. A passivating film 415 is formed on the source pad 410 and the conductive line 412.

Then, a circuit constant is defined by checking an operation of the FET 408. The thin film 430a, a gold layer 430b and the thin film 430c (a stacked layer 431) are patterned by an ion milling method based on the circuit constant so as to form an inductor 430. The inductor 430 has a predetermined inductance responsive to the circuit constant. Also, the inductor 430 can be formed in a spiral type pattern, a ring type pattern or a rectangular type pattern.

Then, a passivating film which comprises of silicon oxide, silicon nitride or strontium oxide is formed on the opposite surface. A portion of the passivating film is removed so as to contact the inductor with a ground line.

According to this preferred embodiment, as it is possible to trim the inductance that is a variable element of the circuit constant in response to a characteristic of the FET formed on the substrate, and a throughput may be improved. As the circuit constant formed on the main surface can be adjusted from the side of the opposite surface, the size of the device can be reduced.

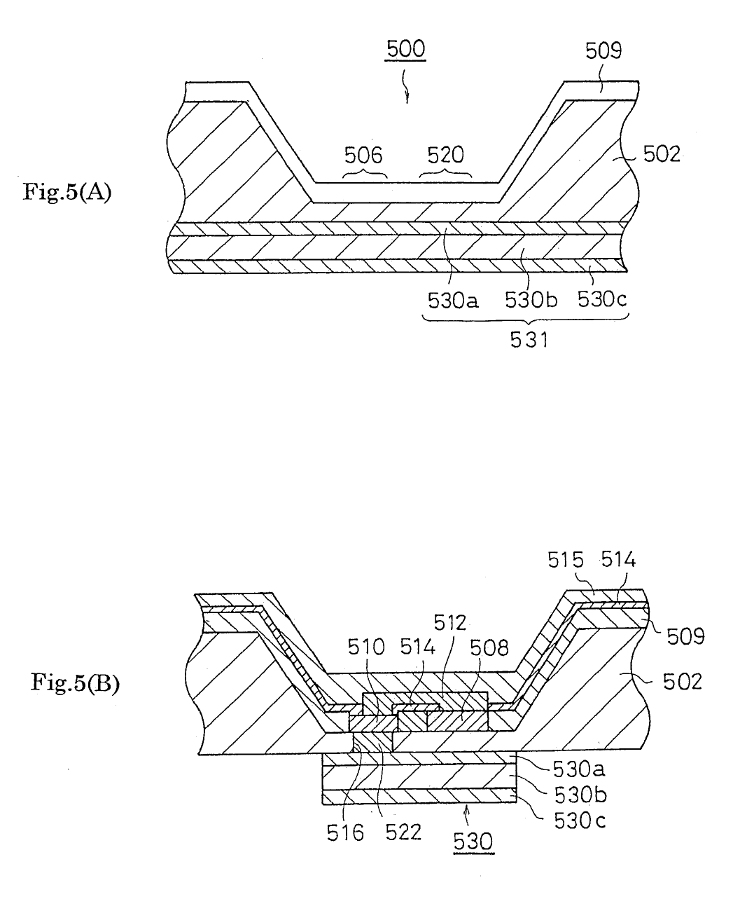

A fifth preferred embodiment will be described hereinafter referring to FIG. 5(A)-FIG. 5(B). In this embodiment, a capacitor is formed on the opposite surface instead of the inductor of the fourth embodiment.

Similar to the fourth embodiment, a recess 500 is formed in a main surface of a GaAs substrate 502, as shown in FIG. 5(A). The recess 500 includes a first region 506 in which a contact hole will be later formed and a second region 520 in which a FET region will be later formed. An impurity layer 509 which includes an impurity is formed on the substrate 502 including an interior surface of the recess 500, as shown in FIG. 5(A).

Then, an opposite surface is polished such the substrate 502 becomes a predetermined thickness. A thin film 530a which is comprised of a refractory metal, such as tungsten (W), is formed on the opposite surface. Then, an insulating layer 530b, such as silicon oxide or strontium oxide is formed on the thin film 530a. Further, a thin layer 530c which is comprised of the refractory metal, such as tungsten (W), is formed on the gold layer 530b.

In FIG. 5(B), a FET region 508 is selectively formed in the impurity layer 509 by an ion implantation method. That is, the FET region 508 is formed on the second region 520 in the recess 500.

Then, a contact hole 516 which reaches the thin film 530a is formed in the first region by etching from the main surface side. A contact metallic layer 522 is filled into the contact hole 516 and a source pad 510 is formed on the contact layer 522, as shown in FIG. 5(B).

Then, an intermediate insulating layer 514 is formed on the impurity layer 509 so as to expose the source pad 510 and the FET region 508. A conductive line 512 which connects the source pad 510 with the FET region 508 is formed on the intermediate insulating layer 514. A passivating film 515 is formed on the source pad 510 and the conductive line 512.

Then, the thin film 430a, a gold layer 430b and the thin film 430c (a stacked layer 531) are patterned by an ion milling method so as to form a capacitor 530 is formed on the opposite surface having a predetermined capacitance responsive to a characteristics of the FET 408. Then, a passivating film which comprises of silicon oxide, silicon nitride or strontium oxide is formed on the opposite surface. A portion of the passivating film is removed so as to contact the capacitor with a ground line.

In the MMIC, a size of a metal-insulator-metal capacitor, such as the capacitor 530, is very large, almost the size of the FETs. Therefore, as the capacitor is formed on the opposite surface of the substrate, a size of the semiconductor device can be reduced by half.

Further, an adjusting element, such as the inductor of the fourth embodiment or the capacitor of the fifth embodiment can be formed by combination of the capacitor and/or the inductor and/or a resistor.

The present invention has been described with reference to illustrative embodiments, however, this description must not be considered to be confined only to the embodiments illustrated. Various modifications and changes of these illustrative embodiments and the other embodiments of the present invention will become apparent to one skilled in the art from reference to the description of the present invention. It is therefore contemplated that the appended claims will cover any such modifications or embodiments as fall within the true scope of the invention.

What is claimed is:

1. A semiconductor device comprising:
a semiconductor substrate which includes a first surface and a second surface opposite to the first surface, wherein the first surface includes a recess which has a bottom region;
a circuit element which is formed in at least the recess on the first surface;
a conductive element which is formed on the second surface;
a conductive line which is connected to the circuit element; and
a contact hole which is formed in the bottom region of the recess and connects the conductive line with the conductive element.

2. The semiconductor device according to claim 1, wherein the circuit element is formed at least in the recess.

3. The semiconductor device according to claim 1 or 2, further comprising
a second recess which is formed in the second surface opposite to the first recess, wherein the contact hole extends to the second recess.

4. The semiconductor device according to claim 1 or 2, wherein the conductive element adjusts an impedance of the circuit element.

5. The semiconductor device according to claim 3, wherein the conductive element adjusts an impedance of the circuit element.

6. The semiconductor device according to claim 4, wherein the conductive element includes an inductor.

7. The semiconductor device according to claim 4, wherein the conductive element includes a conductor.

8. The semiconductor device according to claim 5, wherein the conductive element includes an inductor.

9. The semiconductor device according to claim 5, wherein the conductive element includes a conductor.

10. The semiconductor device according to claim 1 to 2, wherein the semiconductor substrate includes gallium arsenide.

11. A method for fabricating a semiconductor device comprising:
providing a semiconductor substrate having a first surface and a second surface, wherein the first surface is opposite to the second surface;
forming a first recess in the first surface, wherein the first recess has a bottom region;
forming a circuit element on the first surface;
forming a conductive element on the second surface;
forming a conductive layer connected to the circuit element; and
forming a contact hole in the bottom region of the recess, wherein the conductive line is connected with the conductive element via the contact hole.

12. The method according to claim 11, wherein said forming the contact hole includes
polishing the second surface to expose the bottom of the recess from the side of the second surface; and
filling the bottom region with a conductive material.

13. The method according to claim 12, wherein said polishing is carried out such that a depth of the recess becomes substantially equal to a thickness of the semiconductor substrate.

14. The method according to claim 11, further comprising
forming a second recess in the second surface, wherein the second recess has a second bottom region which is opposite to the bottom region of the first recess in the first surface; and
forming the conductive element in the second bottom region of the second recess.

15. The method according to claim 11, 12 or 13, wherein said forming the conductive element on the second surface includes stacking three conductive layers in series.

16. The method according to claim 15, wherein the three metal layers are comprised of a first tungsten layer, a gold layer and a second tungsten layer.

17. The method according to claim 11, 12 or 13, wherein said forming the conductive element on the second surface includes stacking three layers serially, wherein the three layers are comprised of a first conductive layer, an insulating layer and a second conductive layer, wherein the insulating layer is sandwiched between the first and second conductive layers.

18. A semiconductor device comprising:
a semiconductor substrate including a main surface and a opposite surface opposite to the main surface, wherein the semiconductor substrate has a recess;
a first conductive element which is formed on the main surface;
a second conductive element which is formed on the opposite surface; and
a connecting element which electrically connects the first conductive element with the second conductive element, wherein the connecting element is formed in the recess and penetrates through the semiconductor substrate.

19. The semiconductor device according to claim 18, wherein a depth of the recess substantially equals a thickness of the semiconductor substrate.

20. The semiconductor device according to claim 19, wherein the first conductive element comprises an electronic circuit element and is formed in the recess.
